(19) United States
(12) Patent Application Publication
(10) Pub. No.: US 2015/0140833 A1
(43) Pub. Date: May 21, 2015

(54) METHOD OF DEPOSITING A LOW-TEMPERATURE, NO-DAMAGE HDP SIC-LIKE FILM WITH HIGH WET ETCH RESISTANCE

(71) Applicant: Applied Materials, Inc., Santa Clara, CA (US)

(72) Inventors: Kiran V. THADANI, Sunnyvale, CA (US); Abhijit Basu MALLICK, Fremont, CA (US); Nitin INGLE, San Jose, CA (US)

(21) Appl. No.: 14/153,586

(22) Filed: Jan. 13, 2014

Related U.S. Application Data
(60) Provisional application No. 61/905,713, filed on Nov. 18, 2013.

(51) Int. Cl. H01L 21/02

(52) U.S. Cl. CPC H01L 21/02219; H01L 21/02274
USPC 438/762

(57) ABSTRACT

Embodiments of the invention generally relate to methods of forming an etch resistant silicon-carbon-nitrogen layer. The methods generally include activating a silicon-containing precursor and a nitrogen-containing precursor in the processing region of a processing chamber in the presence of a plasma and depositing a thin flowable silicon-carbon-nitrogen material on a substrate using the activated silicon-containing precursor and a nitrogen-containing precursor. The thin flowable silicon-carbon-nitrogen material is subsequently cured using one of a variety of curing techniques. A plurality of thin flowable silicon-carbon-nitrogen material layers are deposited sequentially to create the final layer.

### CROSS-REFERENCE TO RELATED APPLICATIONS

This application claims benefit of U.S. Provisional Patent Application Ser. No. 61/905,713 (APPM/20392L), filed Nov. 18, 2013, which is herein incorporated by reference.

### BACKGROUND

1. Field

Embodiments described herein generally relate to methods of improving etch resistance for flowable films.

2. Description of the Related Art

The miniaturization of semiconductor circuit elements has reached a point where feature sizes of 45 nm, 32 nm, and even 28 nm are fabricated on a commercial scale. As the dimensions continue to get smaller, new challenges arise for seemingly mundane process steps like filling a gap between circuit elements with a dielectric material that acts as electrical insulation. As the width between the elements continues to shrink, the gap between them often gets taller and narrower, making the gap difficult to fill without voids and weak seams. Conventional chemical vapor deposition (CVD) techniques often experience an overgrowth of material at the top of the gap before it has been completely filled. This can create a void or seam in the gap where the depositing dielectric material has been prematurely blocked by the overgrowth; a problem sometimes referred to as breadloafing.

One solution to the breadloafing problem has been to use liquid precursors for the dielectric starting materials that more easily pour into the gaps like filling a glass with water. A technique currently in commercial use for doing this is called spin-on-glass (SOG) and takes a liquid precursor, usually an organo-silicon compound, and spin coats it on the surface of a substrate wafer. While the liquid precursor has fewer breadloafing problems, other problems arise when the precursor material is converted to the dielectric material. These conversions often involve exposing the deposited precursor to conditions that split and drive out the carbon groups in the material, typically by reacting the carbon groups with oxygen to create carbon monoxide and dioxide gas that escapes from the gap. These escaping gases can leave behind pores and bubbles in the dielectric material similar to the holes left behind in baked bread from the escaping carbon dioxide. The increased porosity left in the final dielectric material can have the same deleterious effects as the voids and weak seams created by conventional CVD techniques.

More recently, techniques have been developed that impart flowable characteristics to dielectric materials deposited by CVD. These techniques can deposit flowable precursors to fill a tall, narrow gap without creating voids or weak seams, while avoiding the need to outgas significant amounts of carbon dioxide, water, and other species that leave behind pores and bubbles. Exemplary flowable CVD techniques have used carbon-free silicon precursors that require very little carbon removal after the precursors have been deposited in the gap. The deposition process for these flowable films typically involves a remote plasma source (RPS), in which the high plasma density dissociates the radicals of the main reactant gases, which then react with other precursors further downstream in the chamber and result in a flowable film on the substrate. The film is then cured in other processing chambers to densify the film.

However, this approach of RPS-deposition and cure to process the film suffers from a couple of setbacks. First, since the RPS power is not tunable, the cycles of low-power deposition and high-power cure have to occur in different chambers. Consequently, the film ages between the deposition and cure cycles, reducing the cure efficiency. Further, throughput is significantly reduced. In addition, the penetration depth for the ex situ cure methods is not very high and the film densification is not achieved completely, leading to the detrimental leakage of metals and other species during later integration steps. In wet etch resistant films, such as SiC films, the level of densification is sufficient to achieve wet etch resistance but it is not sufficient to retain the etch resistance during further integration steps involving ashing or dry etch when disruptive elements such as oxygen can seep into the bulk of the film and compromise the previously excellent etch resistance.

Therefore, there is a need for improved methods of improving and maintaining etch resistance in a flowable film.

### SUMMARY OF THE INVENTION

Embodiments of the invention generally relate to methods of improving etch resistance in flowable films. In one embodiment, a method of forming a dielectric layer can include positioning a substrate in a processing region of a processing chamber; delivering a deposition precursor to the processing region, the deposition precursor comprising at least a silicon containing precursor and a nitrogen containing precursor; activating the deposition precursor in the presence of a plasma to deposit a flowable silicon-carbon-nitrogen material on the substrate; and curing the flowable silicon-carbon-nitrogen material in the processing region of the processing chamber.

In another embodiment, a method of forming a dielectric layer can include forming a flowable dielectric layer, the forming comprising delivering a silicon-containing precursor and a nitrogen-containing precursor to a chemical vapor processing chamber; forming a first plasma in the presence of the silicon-containing precursor and the nitrogen containing precursor; reacting the silicon-containing precursor and the nitrogen-containing precursor in the chemical vapor processing chamber, depositing a flowable silicon-carbon-nitrogen material on the substrate; and forming a second plasma to cure the flowable silicon-carbon-nitrogen material; and repeating the forming of the flowable dielectric layer until a desired thickness is achieved.

In another embodiment, a method of forming a dielectric layer can include positioning a substrate in a processing region of a processing chamber; delivering a silicon-containing precursor to the processing region; activating a nitrogen-containing precursor using a remote plasma to create an energized nitrogen-containing precursor; deliver the activated nitrogen-containing precursor to the silicon-containing precursor to deposit a flowable silicon-carbon-nitrogen material on the substrate; and curing the flowable silicon-carbon-nitrogen material in the processing region of the processing chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a system including deposition and curing chambers, according to one or more embodiments;

FIG. 2 depicts a schematic illustration of a substrate processing system that can be used to deposit a flowable silicon-carbon-nitrogen layer, according to one embodiment; and

FIG. 3 is a block diagram of a method for depositing a flowable layer, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention generally relate to methods of improving etch resistance in flowable SiC films. Methods include in situ deposition and cure, where the cure employs direct plasma instead of remote plasma to overcome the above challenges. The methods described herein achieve a dense carbon-containing film, such as an SiC-like film. The film has superior wet etch resistance properties and retains the high etch resistance even during subsequent integration steps (e.g. ashing or dry etch that may incorporate disruptive elements such as oxygen).

The silicon and carbon constituents may come from a silicon and carbon containing precursor while the nitrogen may come from a nitrogen-containing precursor that has been activated to speed the reaction of the nitrogen with the silicon-and-carbon-containing precursor at lower processing chamber temperatures. Exemplary precursors include 1,3,5-trisilapentane (H₃Si—CH₂—SiH₂—CH₂—SiH₃) as the silicon-and-carbon-containing precursor and plasma activated ammonia (NH₃) as the nitrogen-containing precursor. 1,4,7-trisilaheptane may be used to replace or augment the 1,3,5-trisilapentane. When these precursors react in the processing chamber, they deposit a flowable Si—C—N layer on the semiconductor substrate. In those parts of the substrate that are structured with high-aspect ratio gaps, the flowable Si—C—N material may be deposited into those gaps with significantly fewer voids and weak seams.

The initial deposition of the flowable Si—C—N may include significant numbers of Si—H and C—H bonds. These bonds are reactive with the moisture and oxygen in air, as well as a variety of etchants which contributes to an increased rate of film aging and contamination, and higher wet-etch-rate-ratios (WERRs) for the etchants. By depositing using either a local plasma or a remotely generated plasma, followed by a cure using a direct plasma, the flowable Si—C film can be deposited as a thinner film with a reduced number of Si—H bonds and increased number of Si—Si, Si—C, and/or Si—N bonds. The thinner film can be deposited in multiple layers with each layer being cured before subsequent deposition, such that a specific final thickness is achieved.

Following deposition, the Si—C—N film may be cured to further reduce the number of Si—H bonds while also increasing the number Si—Si, Si—C, and/or Si—N bonds in the final film. The curing may also reduce the number of C—H bonds and increases the number of C—N and/or C—C bonds in the final film. Curing techniques include exposing the flowable Si—C—N film to a plasma, such as an inductively coupled plasma (e.g., an HDP-CVD plasma) or a capacitively-coupled plasma (e.g., a PE-CVD plasma). The plasma for curing may be produced either remotely or by an in-situ plasma generating system to perform the plasma treatment following the deposition without removing the substrate from the chamber. This allows the curing step to occur before the initially deposited Si—C—N film has been exposed to moisture and oxygen from the air.

The final Si—C—N film will exhibit increased etch resistance to both conventional oxide and nitride dielectric etchants. For example, the Si—C—N film may have better etch resistance to a dilute hydrofluoric acid solution (DHF) than a silicon oxide film, and also have better etch resistance to a hot phosphoric acid solution than a silicon nitride film. The increased etch resistance to both conventional oxide and nitride etchants allows these Si—C—N films to remain intact during process routines that expose the substrate to both types of etchants. Embodiments herein are more clearly disclosed with reference to the figures below.

Processing chambers that may be used or modified for use with embodiments of the present invention may include high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor processing chambers, among other types of chambers. Specific examples of CVD systems that may implement embodiments of the invention include the CENTURA ULTIMA® HDP-CVD chambers/systems, and PRODUCER® PECVD chambers/systems, available from Applied Materials, Inc. of Santa Clara, Calif. Embodiments of the deposition systems may be incorporated into larger fabrication systems for producing integrated circuit chips.

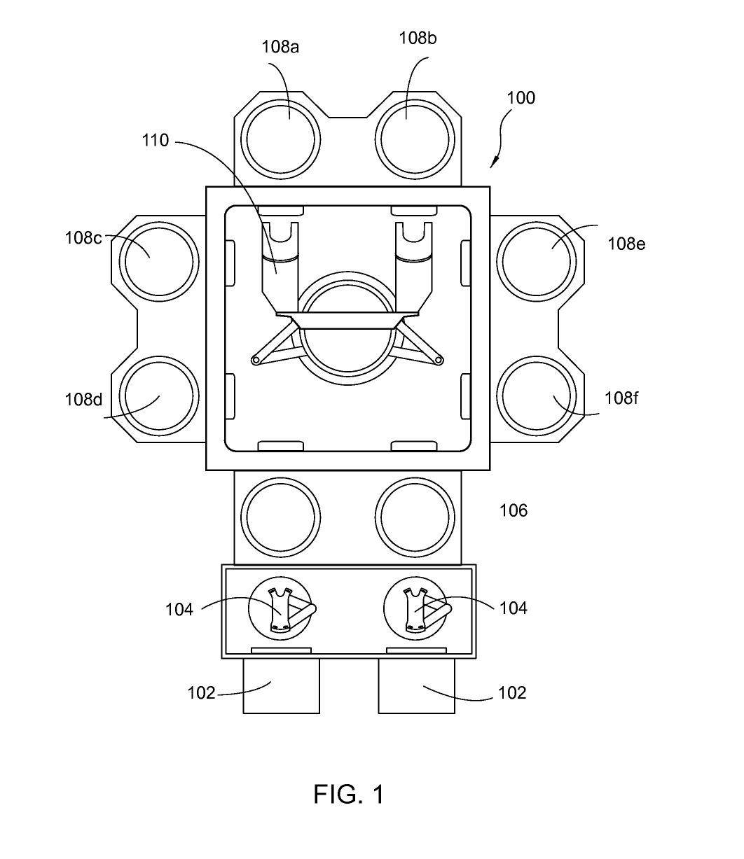

FIG. 1 depicts a system 100 including deposition and curing chambers, according to one or more embodiments. In the figure, a pair of FOUPs (front opening unified pods) 102 supply substrate substrates (e.g., 300 mm diameter wafers) that are received by robotic arms 104 and placed into a low pressure holding area 106 before being placed into one of the wafer processing chambers 108a-108f. A second robotic arm 110 may be used to transport the substrate wafers from the holding area 106 to the processing chambers 108a-108f and back.

The processing chambers 108a-108f can include one or more system components for depositing, annealing, curing and/or etching a flowable dielectric film on the substrate wafer. In one configuration, each of a first group of the processing chambers (e.g., 108c-108f) may be used to deposit and cure the flowable dielectric material on the substrate, and the third group of processing chambers (e.g., 108a-108b) may be used to anneal the deposited dielectric. In another configuration, two pairs of processing chambers (e.g., 108c-108d and 108e-108f) may be configured to both deposit/cure and anneal a flowable dielectric film on the substrate, while the third pair of chambers (e.g., 108a-108b) may be used for UV or E-beam secondary curing of the deposited film. In still another configuration, all three pairs of chambers (e.g., 108a-108f) may be configured to deposit and cure a flowable dielectric film on the substrate. In this embodiment, the chamber would both deposit and cure in situ. In yet another configuration, two pairs of processing chambers (e.g., 108c-108d and 108e-108f) may be used for both deposition and UV or E-beam curing of the flowable dielectric, while a third pair of processing chambers (e.g. 108a-108b) may be used for etching the dielectric film. Any one or more of the processes described may be carried out on chamber(s) separated from the fabrication system shown in different embodiments.

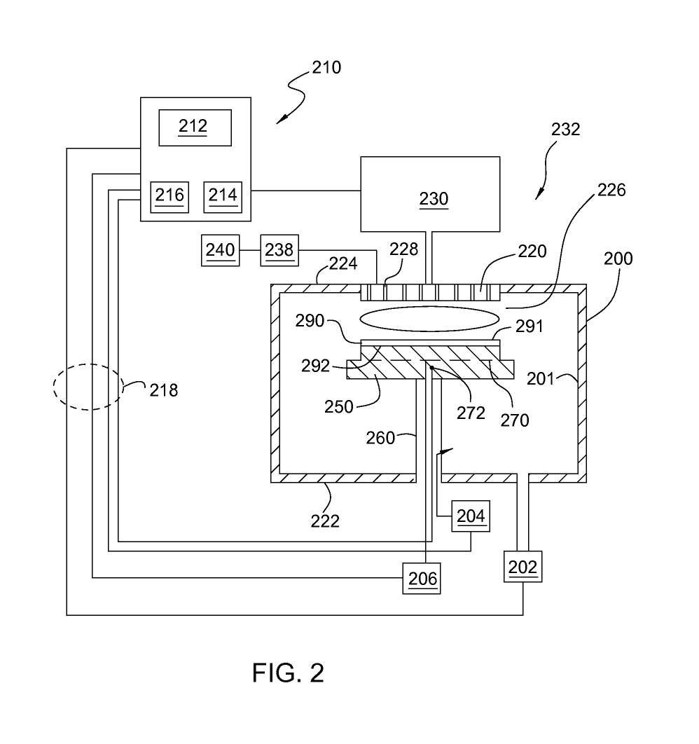

FIG. 2 depicts a schematic illustration of a substrate processing system 232 that can be used to deposit a flowable silicon-carbon-nitrogen layer in accordance with embodiments described herein. The processing system 232 includes a processing chamber 200 coupled to a gas panel 230 and a controller 210. The processing chamber 200 generally includes a top 224, a side 201 and a bottom wall 222 that define an interior processing region 226. A support pedestal 250 is provided in the interior processing region 226 of the chamber 200. The pedestal 250 is supported by a stem 260 and may be typically fabricated from aluminum, ceramic, and other suitable materials. The pedestal 250 may be moved in a vertical direction inside the chamber 200 using a displacement mechanism (not shown).

The pedestal 250 may include an embedded heater element 270 suitable for controlling the temperature of a substrate 290 supported on a surface 292 of the pedestal 250. The pedestal 250 may be resistively heated by applying an electric current from a power supply 206 to the heater element 270. The heater element 270 may be made of a nickel-chromium wire encapsulated in a nickel-iron-chromium alloy (e.g., INCOLOY®) sheath tube. The electric current supplied from the power supply 206 is regulated by the controller 210 to control the heat generated by the heater element 270, thereby maintaining the substrate 290 and the pedestal 250 at a substantially constant temperature during film deposition. The supplied electric current may be adjusted to selectively control the temperature of the pedestal 250 between about 100 degrees Celsius to about 700 degrees Celsius, such as from about 200 degrees Celsius to about 500 degrees Celsius. The pedestal 250 may also include a chiller (not shown) suitable for lowering the temperature of a substrate 290 supported on a surface 292 of the pedestal 250. The chiller may be adjusted to selectively lower the temperature of the pedestal 250 to temperatures of about −10 degrees Celsius or lower.

A temperature sensor 272, such as a thermocouple, may be embedded in the support pedestal 250 to monitor the temperature of the pedestal 250 in a conventional manner. The measured temperature is used by the controller 210 to control the power supplied to the heating element 270 to maintain the substrate at a desired temperature.

A vacuum pump 202 is coupled to a port formed in the bottom of the chamber 200. The vacuum pump 202 is used to maintain a desired gas pressure in the processing chamber 200. The vacuum pump 202 also evacuates post-processing gases and by-products of the process from the chamber 200.

The processing system 232 may further include additional equipment for controlling the chamber pressure, for example, valves (e.g. throttle valves and isolation valves) positioned between the processing chamber 200 and the vacuum pump 202 to control the chamber pressure.

A showerhead 220 having a plurality of apertures 228 is disposed on the top of the processing chamber 200 above the substrate support pedestal 250. The apertures 228 of the showerhead 220 are utilized to introduce process gases into the chamber 200. The apertures 228 may have different sizes, number, distributions, shape, design, and diameters to facilitate the flow of the various process gases for different process requirements. The showerhead 220 is connected to the gas panel 230 that allows various gases to supply to the interior processing region 226 during process.

The showerhead 220 and substrate support pedestal 250 may form a pair of spaced apart electrodes in the interior processing volume 226. One or more RF power sources 240 provide a bias potential through a matching network 238 to the showerhead 220 to facilitate generation of plasma between the showerhead 220 and the pedestal 250. Alternatively, the RF power sources 240 and matching network 238 may be coupled to the showerhead 220, substrate pedestal 250, or coupled to both the showerhead 220 and the substrate pedestal 250, or coupled to an antenna (not shown) disposed exterior to the chamber 200. A plasma is formed from the process gas mixture exiting the showerhead 220 to enhance thermal decomposition of the process gases resulting in the deposition of material on a surface 291 of the substrate 290. The plasma formed herein can be either an inductively coupled plasma (ICP), a microwave plasma (MWP) or a capacitively coupled plasma (CCP).

In a CCP embodiment, the showerhead 220 and substrate support pedestal 250 may form a pair of spaced apart electrodes in the interior processing region 226. One or more RF power sources 240 provide a bias potential through a matching network 238 to the showerhead 220 to facilitate generation of plasma between the showerhead 220 and the pedestal 250. Alternatively, the RF power sources 240 and matching network 238 may be coupled to the showerhead 220, substrate pedestal 250, or coupled to both the showerhead 220 and the substrate pedestal 250, or coupled to an antenna (not shown) disposed exterior to the chamber 200. In one embodiment, the RF power sources 240 may provide between about 100 Watts and about 3,000 Watts at a frequency of about 50 kHz to about 13.6 MHz for a 300 mm substrate. In another embodiment, the RF power sources 240 may provide between about 500 Watts and about 4,000 Watts at a frequency of about 50 kHz to about 13.6 MHz for a 300 mm substrate.

In the embodiment shown, showerhead 220 may distribute process gases which contain oxygen, hydrogen, silicon, carbon and/or nitrogen. In embodiments, the process gas introduced into the interior processing region 226 may contain one or more of oxygen (O₂), ozone (O₃), N₂O, NO, NO₂, NH₃, NₓH_{y} including N₂H₄, silane, disilane, TSA, DSA, and alkyl amines. The process gas may also include a carrier gas such as helium, argon, nitrogen (N₂), etc. The second channel (not shown) may also deliver a process gas and/or a carrier gas, and/or a film-curing gas (e.g. O₃) used to remove an unwanted component from the growing or as-deposited film. Plasma effluents may include ionized or neutral derivatives of the process gas and may also be referred to herein as a radical-oxygen precursor and/or a radical-nitrogen precursor referring to the atomic constituents of the process gas introduced.

The controller 210 includes a central processing unit (CPU) 212, a memory 216, and a support circuit 214 utilized to control the process sequence and regulate the gas flows from the gas panel 230. The CPU 212 may be of any form of a general purpose computer processor that may be used in an industrial setting. The software routines can be stored in the memory 216, such as random access memory, read only memory, floppy, or hard disk drive, or other form of digital storage. The support circuit 214 is conventionally coupled to the CPU 212 and may include cache, clock circuits, input/output systems, power supplies, and the like. Bi-directional communications between the controller 210 and the various components of the processing system 232 are handled through numerous signal cables collectively referred to as signal buses 218, some of which are illustrated in FIG. 2.

Other processing chambers may also benefit from the present invention and the parameters listed above may vary according to the particular processing chamber used to form the flowable layer. For example, other processing chambers may have a larger or smaller volume, requiring gas flow rates that are larger or smaller than those recited for processing chambers available from Applied Materials, Inc.

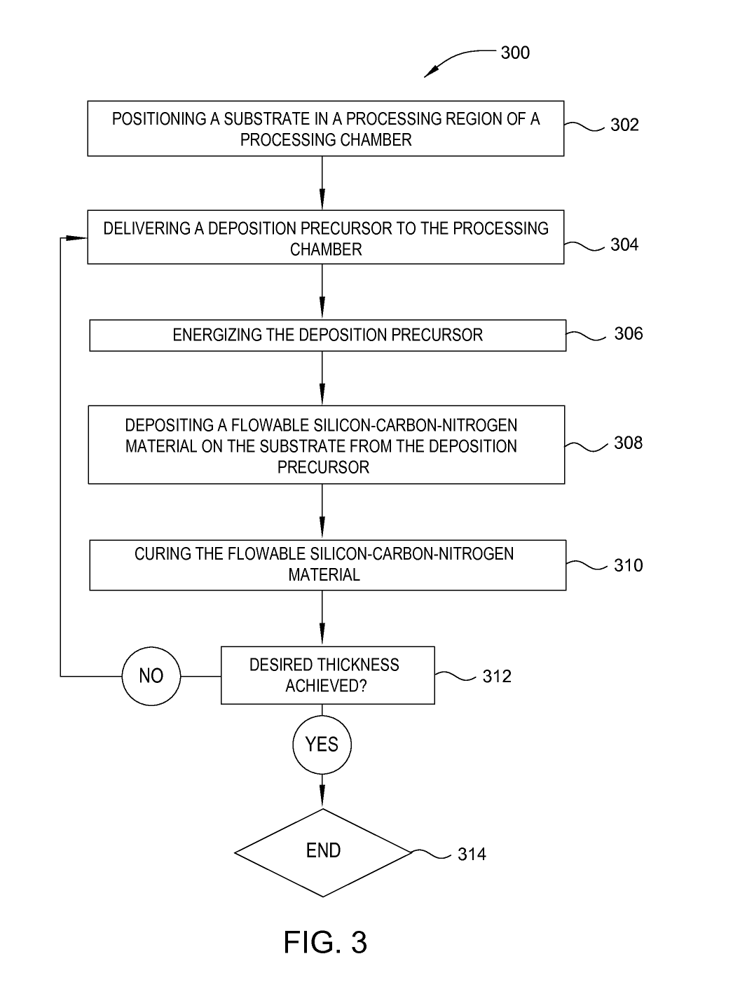

FIG. 3 is a block diagram of a method 300 for depositing a flowable layer, according to one or more embodiments. The method 300 begins by positioning a substrate in a processing chamber, as in element 302. In one embodiment, the processing chamber is a chamber as described with reference to FIG. 2. In another embodiment, the processing chamber is any chamber which is capable of producing a plasma in the processing region of the processing chamber, including chambers modified to produce the same. The substrate can be any substrate used in the deposition of thin films, such as a silicon substrate.

Once the substrate is positioned in the processing chamber, a deposition precursor is delivered to the processing region of the processing chamber, as in element 304. The deposition precursor can include a silicon-containing precursor and a nitrogen containing precursor. The silicon-containing precursor may provide a silicon constituent and a carbon component. Exemplary silicon-containing precursors include 1,3,5-trisilapentane, 1,4,7-trisilaheptane, disilacyclobutane, trisilacyclohexane, 3-methylsilane, silacyclopentene, silacyclobutane, and trimethylsilylacetylene, among others.

Additional exemplary silicon-containing precursors may include mono-, di-silanes, tri-silanes, tetra-silanes, and penta-silanes where one or more central silicon atoms are surrounded by hydrogen and/or saturated and/or unsaturated alkyl groups. Examples of these precursors may include SiR₄, Si₂R₆, Si₃R₈, Si₄R₁₀, and Si₅R₂, where each R group is independently hydrogen (—H) or a saturated or unsaturated alkyl group.

More exemplary silicon-containing precursors may include disilylalkanes having the formula R₃Si—[CR₂]x-SiR₃, where each R is independently a hydrogen (—H), alkyl group (e.g., —CH₃, —CₘH₂ₘ₊₂, where m is a number from 1 to 10), unsaturated alkyl group (e.g., —CH═CH₂), and where x is a number for 0 to 10. Exemplary silicon precursors may also include trisilanes having the formula R₃Si—[CR₂]ₓSiR₂—[CR₂]—SiR₃, where each R is independently a hydrogen (—H), alkyl group (e.g., —CH₃, —CₘH₂ₘ₊₂, where m is a number from 1 to 10), unsaturated alkyl group (e.g., —CH═CH₂), and where x and y are independently a number from 0 to 10. Exemplary silicon-containing precursors may further include silylalkanes and silylalkenes of the form R₃Si—[CH₂]ₙ—[SiR₃]m-[CH₂]ₙ—SiR₃, wherein n and m may be independent integers from 1 to 10, and each of the R groups are independently a hydrogen (—H), methyl (—CH₃), ethyl (—CH₂CH₃), ethylene (—CHCH₂), propyl (—CH₂CH₂CH₃), isopropyl (—CHCH₃CH₃), etc.

Exemplary silicon-containing precursors may further include polysilylalkane compounds may also include compounds with a plurality of silicon atoms that are selected from compounds with the formula R—[(CR₂)ₓ—(SiR₂)_{y}—(CR₂)_{z}]ₙ—R, wherein each R is independently a hydrogen (—H), alkyl group (e.g., —CH₃, —CₘH₂ₘ₊₂, where m is a number from 1 to 10), unsaturated alkyl group (e.g., —CH═CH₂), or silane group (e.g. —SiH₃, —(Si₂H₂)ₘ—SiH₃, where m is a number from 1 to 10)), and where x, y, and z are independently a number from 0 to 10, and n is a number from 0 to 10. In disclosed embodiments, x, y, and z are independently integers between 1 and 10 inclusive. x and z are equal in embodiments of the invention and y may equal 1 in some embodiments regardless of the equivalence of x and z. Variable n may be 1 in some embodiments.

For example when both R groups are —SiH₃, the compounds will include polysilylalkanes having the formula H₃Si—[(CH₂)ₓ—(SiH₂)_{y}—(CH₂)_{z}]ₙ—SiH₃. The silicon-containing compounds may also include compounds having the formula R—[(CR′₂)ₓ—(SiR″₂)_{y}—(CR′₂)_{z}]ₙ—R, where each R, R′, and R″ are independently a hydrogen (—H), an alkyl group (e.g., —CH₃, —CₘH₂ₘ₊₂, where m is a number from 1 to 10), an unsaturated alkyl group (e.g., —CH═CH₂), a silane group (e.g., —SiH₃, —(Si₂H₂)ₘ—SiH₃, where m is a number from 1 to 10), and where x, y and z are independently a number from 0 to 10, and n is a number from 0 to 10. In some instances, one or more of the R′ and/or R″ groups may have the formula —[(CH₂)ₓ—(SiH₂)_{y}—(CH₂)ₓ]ₙ—R′″, wherein R′″ is a hydrogen (—H), alkyl group (e.g., —CH₃, —CₘH₂ₘ₊₂, where m is a number from 1 to 10), unsaturated alkyl group (e.g., —CH═CH₂), or silane group (e.g., —SiH₃, —(Si₂H₂)ₘ—SiH₃, where m is a number from 1 to 10)), and where x, y, and z are independently a number from 0 to 10, and n is a number from 0 to 10.

Still more exemplary silicon-containing precursors may include silylalkanes and silylalkenes such as R₃Si—[CH₂]ₙ—SiR₃, wherein n may be an integer from 1 to 10, and each of the R groups are independently a hydrogen (—H), methyl (—CH₃), ethyl (—C₂CH₃), ethylene (—CHCH₂), propyl (—CH₂CH₂CH₃), isopropyl (—CHCH₃CH₃), etc. They may also include silacyclopropanes, silacyclobutanes, silacyclopentanes, silacyclohexanes, silacycloheptanes, silacyclooctanes, silacyclononanes, silacyclopropenes, silacyclobutenes, silacyclopentenes, silacyclohexenes, silacycloheptenes, silacyclooctenes, silacyclononenes, etc.

Exemplary silicon-containing precursors may further include one or more silane groups bonded to a central carbon atom or moiety. These exemplary precursors may include compounds of the formula H_{4-x-y}CX_{y}(SiR₃)ₓ, where x is 1, 2, 3, or 4, y is 0, 1, 2 or 3, each X is independently a hydrogen or halogen (e.g. F, Cl, Br), and each R is independently a hydrogen (—H) or an alkyl group. Exemplary precursors may further include compounds where the central carbon moiety is a C₂-C₆ saturated or unsaturated alkyl group such as a (SiR₃)ₓC═C(SiR₃)ₓ, where x is 1 or 2, and each R is independently a hydrogen (—H) or an alkyl group.

The silicon-containing precursors may also include nitrogen moieties. For example the precursors may include Si—N and N—Si—N moieties that are substituted or unsubstituted. For example, the precursors may include a central Si atom bonded to one or more nitrogen moieties represented by the formula R₄₋ₓSi(NR₂)ₓ, where x may be 1, 2, 3, or 4, and each R is independently a hydrogen (—H) or an alkyl group. Additional precursors may include a central N atom bonded to one or more Si-containing moieties represented by the formula R_{4-y}N(SiR₃)_{y}, where y may be 1, 2, or 3, and each R is independently a hydrogen (—H) or an alkyl group. Further examples may include cyclic compounds with Si—N and Si—N—Si groups incorporated into the ring structure. For example, the ring structure may have three (e.g., cyclopropyl), four (e.g., cyclobutyl), five (e.g., cyclopentyl), six (e.g., cyclohexyl), seven (e.g., cycloheptyl), eight (e.g., cyclooctyl), nine (e.g., cyclononyl), or more silicon and nitrogen atoms. Each atom in the ring may be bonded to one or more pendant moieties such as hydrogen (—H), an alkyl group (e.g., —CH₃), a silane (e.g., —SiR₃), an amine (—NR₂), among other groups.

In embodiments where there is a desire to form the Si—C—N film with low (or no) oxygen concentration, the silicon-precursor may be selected to be an oxygen-free precursor that contains no oxygen moieties. In these instances, conventional silicon CVD precursors, such as tetraethyl orthosilicate (TEOS) or tetramethyl orthosilicate (TMOS), would not be used as the silicon-containing precursor.

Additional embodiments may also include the use of a carbon-free silicon source such as silane (SiH₄), and silyl-amines (e.g., N(SiH₃)₃) among others. The carbon source may come from a separate precursor that is either independently provided to the processing chamber or mixed with the silicon-containing precursor. Exemplary carbon-containing precursors may include organosilane precursors, and hydrocarbons (e.g., methane, ethane, etc.). In some instances, a silicon-and-carbon containing precursor may be combined with a carbon-fee silicon precursor to adjust the silicon-to-carbon ratio in the deposited film.

In combination with the silicon-containing precursor, a nitrogen-containing precursor may added to the processing chamber in one embodiment. The nitrogen-containing precursor may contribute some or all of the nitrogen constituent in the deposited Si—C—N film. Exemplary sources for the nitrogen-containing precursor may include ammonia (NH₃), hydrazine (N₂H₄), amines, NO, N₂O, and NO₂, among others. The nitrogen-containing precursor may be accompanied by one or more additional gases such a hydrogen (H₂), nitrogen (N₂), helium, neon, argon, etc. The nitrogen-precursor may also contain carbon that provides at least some of the carbon constituent in the deposited Si—C—N layer. Exemplary nitrogen-precursors that also contain carbon include alkyl amines.

Then, the deposition precursor is energized, as in element 306. The deposition precursor or a component thereof can be energized either remotely or directly. Further, the deposition precursor can be energized by an energized component (e.g. energized nitrogen containing gas added to a silicon-containing gas) or it can be energized after it is combined (e.g. by a plasma formed in the processing region of the processing chamber). The plasma may be a capacitively-coupled plasma, a microwave plasma or an inductively-coupled plasma. For example, an inductively-coupled plasma may be formed in an HDP-CVD processing chamber, a microwave plasma may be formed in a MW-PECVD processing chamber, and a capacitively-coupled plasma may be formed in a PECVD processing chamber. In one embodiment, the plasma used to energize the deposition gas is generated in the processing region of the processing chamber.

In one embodiment, an AC voltage typically in the radio frequency (RF) range is applied to ignite a plasma in processing region during deposition. An RF power supply generates a high RF frequency of 13.56 MHz but may also generate other frequencies alone or in combination with the 13.56 MHz frequency. Exemplary RF frequencies include microwave frequencies such as 2.4 GHz. The plasma power for either the CCP plasma or the ICP plasma may be less than or about 300 Watts, less than or about 200 Watts, less than or about 100 Watts or less than or about 50 Watts in embodiments described herein, during deposition of the flowable film. In one embodiment, the plasma power is between 100 mWatts and 200 Watts.

Due to the presence of the plasma during deposition in this embodiment, the deposition may be done at lower temperatures. For example, the plasma treatment region of the chamber may be about 300 degrees Celsius or less, about 250 degrees Celsius or less, about 225 degrees Celsius or less, about 200 degrees Celsius or less, etc. For example, the plasma treatment region may have a temperature of about 100 degrees Celsius to about 300 degrees Celsius. The temperature of the substrate may be about −10 degrees Celsius or more, about 25 degrees Celsius or more, about 50 degrees Celsius or more, about 100 degrees Celsius or more, about 125 degrees Celsius or more, about 150 degrees Celsius or more, etc. For example, the substrate temperature may have a range of about 25 degrees Celsius to about 150 degrees Celsius. The pressure in the plasma treatment region may depend on the plasma treatment (e.g., CCP versus ICP), but typically ranges on the order of mTorr to tens of Torr. In one embodiment, the deposition precursor can be delivered at pressure between 500 mTorr and 2 Torr, such as 1.5 Torr.

In another embodiment, the nitrogen-containing gas is converted to nitrogen-containing plasma effluents using a plasma formed in a remote plasma system (RPS) positioned outside the deposition chamber. The nitrogen-containing precursor may be exposed to the remote plasma where the precursor is dissociated, radicalized, and/or otherwise transformed into the nitrogen-containing plasma effluents. For example, when the source of nitrogen-containing precursor is NH₃, nitrogen-containing plasma effluents may include one or more of ⁺N, ⁺NH, ⁺NH₂, nitrogen radicals. The plasma effluents are then introduced to the deposition chamber, where they mix for the first time with the independently introduced deposition precursor, which in this case would be the silicon-containing precursor.

Alternatively or in addition, the nitrogen-containing precursor may be energized in a plasma region inside the deposition chamber. This plasma region may be partitioned from the deposition region where the precursors mix and react to deposit the flowable silicon-carbon-and-nitrogen-containing layer on the exposed surfaces of the substrate. In these instances, the deposition region may be described as a “plasma free” region during the deposition process. It should be noted that “plasma free” does not necessarily mean the region is devoid of plasma. The borders of the plasma in the chamber plasma region are hard to define and may encroach upon the deposition region through, for example, the apertures of a showerhead used to transport the precursors to the deposition region. If an inductively-coupled plasma is incorporated into the deposition chamber, a small amount of ionization may be initiated in the deposition region during a deposition.

In the described remote plasma embodiments, the nitrogen-containing plasma effluents and the silicon-containing precursor may react to form an initially-flowable silicon-carbon-and-nitrogen layer on the substrate. The temperature in the reaction region of the deposition chamber may be low (e.g., less than 100 degrees Celsius) and the total chamber pressure may be about 0.1 Torr to about 10 Torr (e.g., about 0.5 to about 6 Torr, etc.) during the deposition of the silicon-carbon-and-nitrogen layer. The temperature may be controlled in part by a temperature controlled pedestal that supports the substrate. The pedestal may be thermally coupled to a cooling/heating unit that adjust the pedestal and substrate temperature to, for example, about −10 degrees Celsius to about 200 degrees Celsius. In some instances the additional gases may also be at least partially dissociated and/or radicalized by the plasma, while in other instances the additional gases may act as a dilutant/carrier gas.

The deposition precursor then reacts to deposit a flowable silicon-carbon-nitrogen material on the substrate, as in element 308. The nitrogen-containing precursor and the silicon-containing precursor, energized as described above, may react to form a flowable silicon-carbon-nitrogen layer on the substrate. The temperature in the reaction region of the processing chamber may be low (e.g., less than 100 degrees Celsius) and the total chamber pressure may be about 0.1 Torr to about 10 Torr (e.g., about 0.5 to about 6 Torr, etc.) during the deposition of the silicon-carbon-nitrogen film. The temperature may be controlled in part by a temperature controlled pedestal that supports the substrate. The pedestal may be thermally coupled to a cooling/heating unit that adjust the pedestal and substrate temperature to, for example, about −10 degrees Celsius to about 200 degrees Celsius.

The initially flowable silicon-carbon-nitrogen layer may be deposited on exposed planar surfaces a well as into gaps. The deposition thickness may be less than 50 Å (e.g., about 40 Å, about 35 Å, about 30 Å, about 25 Å, about 20 Å, etc.) In one embodiment, the deposited layer is between 20 Å and 50 Å.

The flowability of the initially deposited silicon-carbon-nitrogen layer may be due to a variety of properties which result from mixing the precursors, energized as described above. These properties may include a significant hydrogen component in the initially deposited silicon-carbon-nitrogen layer as well as the present of short-chained polysilazane polymers. The flowability does not rely on a high substrate temperature, therefore, the initially-flowable silicon-carbon-and-nitrogen-containing layer may fill gaps even on relatively low temperature substrates. During the formation of the silicon-carbon-and-nitrogen-containing layer, the substrate temperature may be below or about 400 degrees Celsius, below or about 300 degrees Celsius, below or about 200 degrees Celsius, below or about 150 degrees Celsius. or below or about 100 degrees Celsius, in one or more embodiments.

When the flowable silicon-carbon-nitrogen layer reaches a desired thickness, the process effluents may be removed from the processing chamber. These process effluents may include any unreacted nitrogen-containing and silicon-containing precursors, dilutent and/or carrier gases, and reaction products that did not deposit on the substrate. The process effluents may be removed by evacuating the processing chamber and/or displacing the effluents with non-deposition gases in the deposition region.

Following the initial deposition of the silicon-carbon-nitrogen layer and optional removal of the process effluents, the flowable silicon-carbon-nitrogen material can be cured into a dielectric layer, as in element 310. In this embodiment, a cure may be performed to reduce the number of Si—H and/or C—H bonds in the layer, while also increasing the number of Si—Si, Si—C, Si—N, and/or C—N bonds. As noted above, a reduction in the number of these bonds may be desired after the deposition to harden the layer and increase its resistance to etching, aging, and contamination, among other forms of layer degradation.

Curing techniques may include exposing the initially deposited layer to a plasma of one or more treatment gases such as helium, nitrogen, argon, etc. The temperature range can be the same as the temperature range for deposition. The temperature for deposition and curing can be independently selected. The plasma power for either the CCP plasma or the ICP plasma may be less than or about 5000 Watts, less than or about 4000 Watts, less than or about 3000 Watts or less than or about 2000 Watts in embodiments described herein, during deposition of the flowable film. In one embodiment, the plasma power is between 200 Watts and 4000 Watts. Process gases for the formation of the curing plasma include argon, helium, nitrogen and inert gases.

Curing techniques which may be used also include high density plasma (HDP) cure, ultraviolet (UV) cure, e-beam cure, thermal cure and microwave cure. Techniques such as UV cure may require increased temperatures, such as a temperature between 200 degrees Celsius and 600 degrees Celsius. These curing techniques can be performed using parameters such as time, intensity, temperature and exposure which are well known in the art.

Once the layer has been cured, the process can be repeated one or more times until a desired thickness is achieved. The final silicon-carbon-nitrogen layer may be the accumulation of two or more deposited silicon-carbon-nitrogen layers that have undergone a treatment step before the deposition of the subsequent layer. The final deposition thickness may be about 400 Å or more (e.g., about 400 Å, about 450 Å, about 500 Å, about 550 Å, about 600 Å, about 650 Å, about 700 Å, etc.). In one embodiment, the final deposition thickness is between 500 Å and 2000 Å. For example, the silicon-carbon-nitrogen layer may be a 1200 Å thick layer. This layer can consist of 40 deposited and treated layers, each layer being about 30 Å thick. In another example, the silicon-carbon-nitrogen layer may be a 1500 Å thick layer. This layer can consist of 35 deposited and treated layers, each layer being between about 20 Å and about 50 Å thick. The number of cycles of deposition and cure will depend on the total target thickness.

Methods described herein can be used to form a flowable silicon-carbon-nitrogen material layer with high etch resistance. Previous films can achieve good wet etch resistance. However, after subsequent O₂ ashing steps, the wet etch resistance can be lost. By performing an in situ deposition and cure process as described here, the film can be densified while preventing oxygen seepage, which will maintain the wet etch resistance even after O₂ ashing.

While the foregoing is directed to embodiments of the present invention, other and further embodiments of the invention may be devised without departing from the basic scope thereof, and the scope thereof is determined by the claims that follow.

We claim:

1. A method of forming a dielectric layer, comprising:
positioning a substrate in a processing region of a processing chamber;
delivering a deposition precursor to the processing region, the deposition precursor comprising at least a silicon containing precursor and a nitrogen containing precursor;
activating the deposition precursor in the presence of a plasma to deposit a flowable silicon-carbon-nitrogen material on the substrate; and
curing the flowable silicon-carbon-nitrogen material in the processing region of the processing chamber.

2. The method of claim 1, wherein the flowable silicon-carbon-nitrogen material is between 20 Å and 50 Å.

3. The method of claim 1, wherein the silicon-containing precursor comprises 1,3,5-trisilapentane, 1,4,7-trisilaheptane, disilacyclobutane, trisilacyclohexane, 3-methylsilane, silacyclopentene, silacyclobutene, or trimethylsilylacetylene.

4. The method of claim 1, wherein the plasma is an inductively coupled or capacitively coupled plasma.

5. The method of claim 1, further comprising delivering the deposition precursor, activating the deposition precursor, curing the flowable silicon-carbon-nitrogen material one or more times to achieve a desired thickness.

6. The method of claim 1, wherein curing the flowable silicon-carbon-nitrogen material comprises one of a plasma cure, an high density plasma cure, a UV cure, an e-beam cure, a thermal cure or a microwave cure.

7. The method of claim 6, wherein curing the flowable silicon-carbon-nitrogen material comprises an inductively or capacitively coupled plasma cure formed using an inert gas.

8. The method of claim 6, wherein the inert gas comprises argon, helium, nitrogen or combinations thereof.

9. The method of claim 1, wherein the nitrogen-containing precursor comprises ammonia.

10. The method of claim 1, wherein the treating of the flowable silicon-carbon-nitrogen material comprises exposing the material to a plasma.

11. The method of claim 1, wherein either the cure is a UV cure performed at a temperature between 200 degrees Celsius and 600 degrees Celsius.

12. A method of forming a dielectric layer, comprising:
forming a flowable dielectric layer, the forming comprising:
delivering a silicon-containing precursor and a nitrogen-containing precursor to a chemical vapor processing chamber;
forming a first plasma in the presence of the silicon-containing precursor and the nitrogen containing precursor;
reacting the silicon-containing precursor and the nitrogen-containing precursor in the chemical vapor processing chamber, depositing a flowable silicon-carbon-nitrogen material on the substrate; and
forming a second plasma to cure the flowable silicon-carbon-nitrogen material; and
repeating the forming of the flowable dielectric layer until a desired thickness is achieved.

13. The method of claim 12, wherein the desired thickness is between 500 Å and 1500 Å.

14. The method of claim 12, wherein the flowable silicon-carbon-nitrogen material is between 20 Å and 50 Å thick.

15. The method of claim 12, wherein the silicon-containing precursor comprises 1,3,5-trisilapentane, 1,4,7-trisilaheptane, disilacyclobutane, trisilacyclohexane, 3-methylsilane, silacyclopentene, silacyclobutene, or trimethylsilylacetylene.

16. The method of claim 12, wherein the nitrogen-containing precursor comprises ammonia.

17. The method of claim 12, wherein the silicon-containing precursor contains both silicon and nitrogen substituents.

18. The method of claim 12, wherein the second plasma is delivered to the surface of the flowable silicon-carbon-nitrogen material.

19. The method of claim 12, wherein the temperature of the processing chamber is maintained between −10 degrees Celsius and 200 degrees Celsius.

20. A method of forming a dielectric layer, comprising:
positioning a substrate in a processing region of a processing chamber;
delivering a silicon-containing precursor to the processing region;
activating a nitrogen-containing precursor using a remote plasma to create an energized nitrogen-containing precursor;
deliver the activated nitrogen-containing precursor to the silicon-containing precursor to deposit a flowable silicon-carbon-nitrogen material on the substrate; and
curing the flowable silicon-carbon-nitrogen material in the processing region of the processing chamber using a direct plasma.
